(19) United States
(12) Patent Application Publication
(10) Pub. No.: US 2022/0013323 A1
(43) Pub. Date: Jan. 13, 2022

(54) HYDROGEN CO-GAS WHEN USING A CHLORINE-BASED ION SOURCE MATERIAL

(71) Applicant: Axcelis Technologies, Inc., Beverly, MA (US)

(72) Inventors: Neil K. Colvin, Merrimack, NH (US); Neil Bassom, Hamilton, MA (US); Xiangyang Wu, Andover, MA (US)

(21) Appl. No.: 17/339,025

(22) Filed: Jun. 4, 2021

Related U.S. Application Data
(60) Provisional application No. 63/050,286, filed on Jul. 10, 2020.

(51) Int. Cl. H01J 37/08; H01J 37/317

(52) U.S. Cl. CPC H01J 37/08; H01J 2237/0815; H01J 37/3171

(57) ABSTRACT

An ion implantation system has an aluminum trichloride source material. An ion source is configured to ionize the aluminum trichloride source material and form an ion beam. The ionization of the aluminum trichloride source material further forms a by-product having a non-conducting material containing chlorine. A hydrogen introduction apparatus is configured to introduce a reducing agent including hydrogen to the ion source. The reducing agent is configured to alter a chemistry of the non-conducting material to produce a volatile gas by-product. A beamline assembly is configured to selectively transport the ion beam, and an end station is configured to accept the ion beam for implantation of ions into a workpiece.

### REFERENCE TO RELATED APPLICATIONS

This application claims the benefit of U.S. Provisional Application Ser. No. 63/050,286 filed Jul. 10, 2020, the contents of all of which are herein incorporated by reference in their entirety.

### FIELD

The present invention relates generally to ion implantation systems, and more specifically to an ion implantation system having a chlorine-based ion source material using a hydrogen co-gas and associated beamline components with mechanisms for in-situ cleaning of the ion implantation system.

### BACKGROUND

In the manufacture of semiconductor devices, ion implantation is used to dope semiconductors with impurities or dopants. Ion beam implanters are used to treat silicon wafers with an ion beam, in order to produce n or p type extrinsic material doping or to form passivation layers during fabrication of an integrated circuit. When used for doping semiconductors, the ion beam implanter injects a selected extrinsic species to produce the desired semiconducting material. Implanting ions generated from source materials such as antimony, arsenic or phosphorus results in “n type” extrinsic material wafers, whereas if “p type” extrinsic material wafers are desired, ions generated with source materials such as boron, or indium may be implanted.

Typical ion beam implanters include an ion source for generating positively charged ions from ionizable source materials. The generated ions are formed into a beam and directed along a predetermined beam path to an implantation station. The ion beam implanter may include beam forming and shaping structures extending between the ion source and the implantation station. The beam forming and shaping structures maintain the ion beam and bound an elongated interior cavity or passageway through which the beam passes en route to the implantation station. When operating an implanter, this passageway can be evacuated to reduce the probability of ions being deflected from the predetermined beam path as a result of collisions with gas molecules.

Ion sources in ion implanters typically generate the ion beam by ionizing a source material in an arc chamber, wherein a component of the source material is a desired dopant element. The desired dopant element is then extracted from the ionized source material in the form of the ion beam.

Conventionally, when aluminum ions are the desired dopant element, materials such as aluminum nitride (AIN) and alumina (Al₂O₃) have been used as a source material of aluminum ions for the purpose of ion implantation. Aluminum nitride or alumina are solid, insulative materials which are typically placed in an arc chamber of the ion source where the plasma is formed.

A gas (e.g., fluorine) is conventionally introduced to chemically etch the aluminum-containing materials, whereby the source material is ionized, and aluminum is extracted and transferred along the beamline to silicon carbide workpiece positioned in an end station for implantation thereto. The aluminum-containing materials, for example, are commonly used with some form of etchant gas (e.g., BF₃, PF₃, NF₃, etc.) in the arc chamber as the source material of the aluminum ions. These materials, however, have the unfortunate side effect of producing insulating material (e.g., AIN, Al₂O₃, AlF₃, etc.) which is emitted along with the intended aluminum ions from the arc chamber. The insulating material subsequently coats various components of the ion source, such as extracting electrodes, which then begin to build an electric charge and unfavorably alter the electrostatic characteristic of the extraction electrodes.

The consequence of the electric charge build-up results in behavior commonly referred to as arcing, or “glitching”, of the extraction electrodes as the built-up charge arcs to other components and or to ground. In extreme cases, behavior of a power supply for the extraction electrodes can be altered and distorted. This typically results in unpredictable beam behavior and leads to reduced beam currents and frequent preventive maintenance to clean the various components associated with the ion source. Additionally, flakes and other residue from these materials can form in the arc chamber, thus altering its operational characteristics, leading to additional frequent cleaning.

### SUMMARY

The present disclosure is directed generally toward an ion implantation system and an ion source material associated therewith. More particularly, the present disclosure is directed toward components for said ion implantation system using a chlorine-based solid source material for producing atomic ions to electrically dope silicon, silicon carbide, or other semiconductor substrates at various temperatures, ranging up to 1000° C. Further, the present disclosure minimizes various deposits on extraction electrodes and source chamber components when using a solid chlorine-based material as an ion source vaporizer material. The present disclosure will thus reduce associated arcing and glitching, and will further increase overall lifetimes of the ion source and associated electrodes.

Accordingly, the following presents a simplified summary of the disclosure in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

In accordance with one aspect of the disclosure, an ion implantation system is provided for implanting ions into a workpiece. An aluminum trichloride source material and an ion source are provided, wherein the ion source is configured to ionize the aluminum trichloride source material to form an ion beam. The ionization of the aluminum trichloride source material, for example, further forms a by-product comprising a non-conducting material containing chlorine. A hydrogen introduction apparatus is further configured to introduce a reducing agent comprising hydrogen to the ion source. The reducing agent, for example, is configured to alter a chemistry of the non-conducting material to produce a volatile gas by-product. According to one example, a beamline assembly is further provided and configured to selectively transport the ion beam. An end station is further configured to accept the ion beam for implantation of ions into the workpiece. A vacuum system, for example, can be further provided and configured to substantially evacuate one or more enclosed portions of the ion implantation system, such as the ion source.

In one example, the hydrogen introduction apparatus comprises a hydrogen co-gas source, wherein the hydrogen from the reducing agent alters the chemistry of the non-conducting material to produce hydrogen chloride. In another example, the hydrogen introduction apparatus comprises a pressurized gas source. The pressurized gas source, for example, comprises one or more of hydrogen gas and phosphine. In yet another example, the non-conducting material containing chlorine comprises a molecule in the form of AlClₓ, where x is a positive integer.

The aluminum trichloride source material, for example, can be in one of a solid form or a powder form. For example, a source material vaporizer can be operably coupled to the ion source, wherein the source material vaporizer is configured to vaporize the aluminum trichloride source material.

In accordance with another example aspect, an ion implantation system is provided, wherein an ion source is configured to ionize a chlorine-based source material and form an ion beam therefrom, whereby the ionization of the chlorine-based source material further forms a by-product comprising a non-conducting material containing chlorine.

A hydrogen introduction apparatus can be further provided and configured to introduce a reducing agent comprising hydrogen to the ion source, wherein the reducing agent is configured to alter a chemistry of the non-conducting material to produce a volatile gas by-product. A beamline assembly can further selectively transport the ion beam to an end station configured to accept the ion beam for implantation of ions into a workpiece.

The hydrogen introduction apparatus, for example, can comprise a hydrogen co-gas source, wherein the hydrogen from the reducing agent alters the chemistry of the non-conducting material to produce hydrogen chloride. The hydrogen introduction apparatus, for example, can comprise a pressurized gas source of one or more of hydrogen gas and phosphine. The chlorine-based source material, for example, can comprise one of aluminum trichloride, germanium (iv) chloride, indium (i) chloride, indium (iii) chloride, gallium (ii) chloride, and gallium (iii) chloride.

According to another example aspect of the disclosure, a method is provided for implanting aluminum ions into a workpiece. In the method, an aluminum trichloride source material is vaporized, and the vaporized aluminum trichloride source material is provided to an ion source of an ion implantation system. A hydrogen co-gas, for example, is further provided to the ion source. The aluminum trichloride source material, for example, is ionized in the ion source, wherein the hydrogen co-gas reacts with the vaporized aluminum trichloride source material within the ion source to produce volatile hydrogen chloride gas. The volatile hydrogen chloride gas is further removed via a vacuum system. Aluminum ions from the ionized aluminum trichloride source material, for example, can be further implanted into a workpiece.

In one example, the aluminum trichloride source material is initially in one of a solid form or a powder form. In another example, providing the hydrogen co-gas to the ion source can comprise providing one or more of hydrogen gas and phosphine to the ion source.

According to yet another example aspect of the disclosure, a method for implanting ions into a workpiece is provided, wherein a chlorine-based source material is vaporized and provided to an ion source of an ion implantation system. A hydrogen co-gas is also provided to the ion source, and the chlorine-based source material is ionized in the ion source, wherein the hydrogen co-gas reacts with the vaporized chlorine-based source material within the ion source to produce volatile hydrogen chloride gas. The volatile hydrogen chloride gas is further removed via a vacuum system. Accordingly, ions from the chlorine-based source material can be further implanted into a workpiece.

To the accomplishment of the foregoing and related ends, the disclosure comprises the features hereinafter fully described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a block diagram of an exemplary vacuum system utilizing a chlorine-based aluminum ion source material in accordance with several aspects of the present disclosure.

FIG. 2 illustrates an exemplary method for implanting ions into a workpiece using a chlorine-based ion source material.

### DETAILED DESCRIPTION

The present disclosure is directed generally toward an ion implantation system and an ion source material associated therewith. More particularly, the present disclosure is directed toward components for said ion implantation system using a chlorine-based solid source material for producing atomic ions to electrically dope silicon, silicon carbide, or other semiconductor substrates at various temperatures, ranging up to 1000° C. Further, the present disclosure minimizes various deposits on extraction electrodes and source chamber components when using a solid chlorine-based material as an ion source vaporizer material. The present disclosure will thus reduce associated arcing and glitching, and will further increase overall lifetimes of the ion source and associated electrodes.

Accordingly, the present invention will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling. Furthermore, it is to be appreciated that functional blocks or units shown in the drawings may be implemented as separate features or circuits in one embodiment, and may also or alternatively be fully or partially implemented in a common feature or circuit in another embodiment. For example, several functional blocks may be implemented as software running on a common processor, such as a signal processor. It is further to be understood that any connection which is described as being wire-based in the following specification may also be implemented as a wireless communication, unless noted to the contrary.

Ion implantation is a physical process that is employed in semiconductor device fabrication to selectively implant dopant into semiconductor and/or wafer material. Thus, the act of implanting does not rely on a chemical interaction between a dopant and semiconductor material. For ion implantation, dopant atoms/molecules from an ion source of an ion implanter are ionized, accelerated, formed into an ion beam, analyzed, and swept across a wafer, or the wafer is translated through the ion beam. The dopant ions physically bombard the wafer, enter the surface and come to rest below the surface, at a depth related to their energy.

The present disclosure seeks to minimize chlorine-based deposits on extraction electrodes and other components associated with an ion source chamber when using a chlorine-based ion source material. In one particular example, the present disclosure minimizes chloride deposits on extraction electrodes and other components associated with an ion source chamber when using aluminum trichloride (AlCl₃) as an ion source material. The present disclosure advantageously reduces glitching or arcing associated with in formation, and further increases overall ion source and electrode lifetimes.

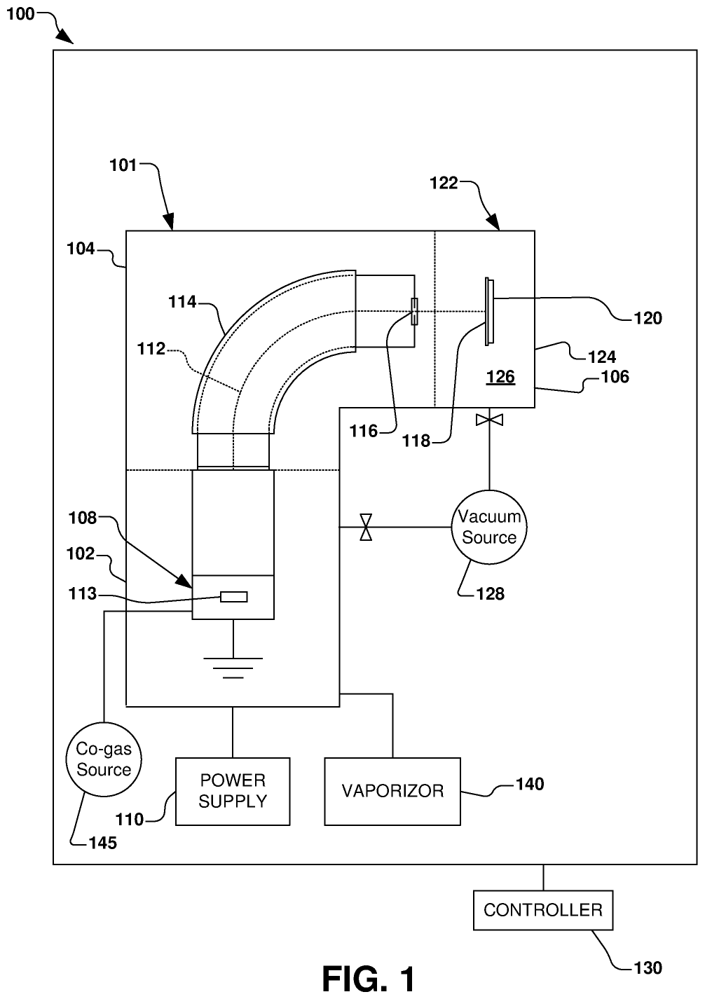

In order to gain a better understanding of the disclosure, in accordance with one aspect of the present disclosure, FIG. 1 illustrates an exemplary vacuum system 100. The vacuum system 100 in the present example comprises an ion implantation system 101, however various other types of vacuum systems are also contemplated, such as plasma processing systems, or other semiconductor processing systems. The ion implantation system 101, for example, comprises a terminal 102, a beamline assembly 104, and an end station 106.

Generally speaking, an ion source 108 in the terminal 102 is coupled to a power supply 110 to ionize a dopant gas into a plurality of ions from the ion source to form an ion beam 112. Individual electrodes in close proximity to the extraction electrode may be biased to inhibit back streaming of neutralizing electrons close to the source or back to the extraction electrode. An ion source material 113 of the present disclosure is provided in the ion source 108, wherein the ion source material comprises a chlorine-based material such as solid aluminum trichloride (AlCl₃), as will be discussed in further detail infra.

The ion beam 112 in the present example is directed through a beam-steering apparatus 114, and out an aperture 116 towards the end station 106. In the end station 106, the ion beam 112 bombards a workpiece 118 (e.g., a semiconductor such as a silicon wafer, a display panel, etc.), which is selectively clamped or mounted to a chuck 120 (e.g., an electrostatic chuck or ESC). Once embedded into the lattice of the workpiece 118, the implanted ions change the physical and/or chemical properties of the workpiece. Because of this, ion implantation is used in semiconductor device fabrication and in metal finishing, as well as various applications in materials science research.

The ion beam 112 of the present disclosure can take any form, such as a pencil or spot beam, a ribbon beam, a scanned beam, or any other form in which ions are directed toward end station 106, and all such forms are contemplated as falling within the scope of the disclosure.

According to one exemplary aspect, the end station 106 comprises a process chamber 122, such as a vacuum chamber 124, wherein a process environment 126 is associated with the process chamber. The process environment 126 generally exists within the process chamber 122, and in one example, comprises a vacuum produced by a vacuum source 128 (e.g., a vacuum pump) coupled to the process chamber and configured to substantially evacuate the process chamber. Further, a controller 130 is provided for overall control of the vacuum system 100.

The present disclosure appreciates that workpieces 118 having silicon carbide-based devices formed thereon have been found to have better thermal and electrical characteristics than silicon-based devices, in particular, in applications used in high voltage and high temperature devices, such as electric cars, etc. Ion implantation into silicon carbide, however, utilizes a different class of implant dopants than those used for silicon workpieces. In silicon carbide implants, aluminum and nitrogen implants are often performed. Nitrogen implants, for example, are relatively simple, as the nitrogen can be introduced as a gas, and provides relatively easy tuning, cleanup, etc. Aluminum, however, is more difficult, as there are presently few good gaseous solutions of aluminum known.

The present disclosure contemplates a chlorine-based ion source material, in conjunction with a hydrogen co-gas, to advantageously provide high ion beam currents with minimal deleterious issues associated with the formation of insulative materials discussed above. In particular, the present disclosure contemplates using aluminum trichloride (AlCl₃) to produce atomic aluminum ions, whereby the aforementioned insulating materials, flakes, etc., are not produced and do not build up, thus extending the lifetime of the ion source and electrodes, producing a more stable ion beam operation, and allowing substantially higher beam currents.

Thus, the present disclosure produces single atom ions, such as aluminum ions, germanium ions, indium ions, and gallium ions, from a chlorine-based material, such as aluminum trichloride (AlCl₃), germanium chloride (GeCl₄), indium chloride (InCl₃), and gallium chloride (GaCl₃), respectively, as a solid source material with the introduction of a hydrogen co-gas to electrically dope a silicon carbide, silicon, or other substrate, at temperatures from room temperature to approximately 1000° C. Such a production of single atom ions advantageously yields improved source lifetimes, higher beam currents, and better operational characteristics than current techniques.

In accordance with the present disclosure, aluminum chloride (AlCl₃ in a powder or other solid form) is inserted into a solid source vaporizer 140 of the ion implantation system 101 (e.g., a suitable ion implanter manufactured by Axcelis Technologies of Beverley, Mass.). The solid source vaporizer 140 associated with the ion source 108, for example, is loaded with aluminum trichloride material in an inert environment (e.g., argon, nitrogen, etc.) so as not to start reacting the material with moisture in the air. The ion source is then installed in an ion implanter and pumped down with vacuum to the implanter's operating pressure. The aluminum trichloride is heated (e.g., approximately 50C) in the vaporizer 140 until it forms a vapor which migrates to the ionization chamber where the aluminum is ionized and extracted down the beamline.

Aluminum trichloride is a hydroscopic temperature-sensitive powdery material that, when heated in the vaporizer 140 of the ion source 108, can produce a generally constant stream of molecules to be introduced into the arc chamber for ion implantation. The molecules are weakly bonded and can be dissociated in the plasma, such as:

AlCl₃→Al(s)+Cl₃ (1).

The inventors speculate that one of the by-products of extraction of AlClₓ is an insulative, non-conducting material that deposits on extraction and suppression electrodes of the ion source 108, thus causing charging and subsequent arcing in high electric fields. Such arcing or “glitches” associated with the extraction and suppression electrodes affect the utilization and stability of the ion beam 112. The inventors have also observed that electrical ground returns in these high voltage stress areas become coated with such non-conducting materials and charge and discharge due to the presence of secondary electrons generated by the ion beam 112.

The present disclosure thus provides an introduction of a reducing agent, such as hydrogen, to the ion source 108 from a hydrogen co-gas source 145 to alter the chemistry of this insulative material to make a volatile compound (e.g., HCl) to be pumped away via the vacuum source 128. The reducing agent, for example, comprises a hydrogen co-gas. The following equation provides one example using aluminum trichloride:

2 AlCl₃+3H₂→6 HCl+2 Al (2).

As such, the present disclosure introduces a reducing agent, such as hydrogen, to the ion source 108 from a hydrogen co-gas source 145, whereby the reducing agent alters the chemistry of the non-conducting material to convert it a volatile gas by-product (e.g., hydrogen chloride, HCl). The kinetics of the reaction from chlorine and hydrogen of equation (2) is favorable, as it reduces the overall energy after forming the volatile gas by-product (HCl). The volatile gas by-product (HCl), for example, is continuously pumped away as it forms.

Aluminum trichloride, for example, vaporizes at approximately 50C. Conventionally, when there was no introduction of hydrogen from the hydrogen co-gas source 145 of the present disclosure, the ion source 108 can transition the aluminum chloride to vapor phase at undesirable times, thus causing arcing between electrodes in the arc chamber, thus making the use of aluminum trichloride heretofore undesirable due to instabilities to the system. The inventors have found that by providing the hydrogen co-gas above a predetermined level, however, the arcing dissipates, and the ion source can operate smoothly and at higher currents than previously thought attainable.

The inventors theorize that the hydrogen co-gas “ties up” the chlorine and makes hydrochloric acid (HCl) to etch any insulative AlClₓ (where x is a whole number greater than 0) that is produced, and which could otherwise coat electrodes or surfaces, deleterious causing charging/discharging. As such, since the chlorine is tied up by the hydrogen co-gas to produce HCl, deposited material(s) can be advantageously etched off the electrode or surface while operating the ion source 108, thus mitigating previous issues concerning material delamination or insulative coatings on electrodes or surfaces. For example, if a surface or electrode has aluminum chloride deposited on it, the aluminum chloride will begin to insulate the electrode. However, by utilizing the hydrogen co-gas of the present disclosure, the chlorine is tied up to make the HCl, thus stopping it from discharging.

Further, when operating with a conventional gas ring around the body of the ion source 108 in attempts to prevent depositions of AlCl, AlCl₂ or other materials around the body, a formation of hydrochloric acid, which is hygroscopic, can occur, yielding reactions resulting in AlOH₃ and 3 HCl and some water. As such, without the hydrogen co-gas of the present disclosure, a significant amount of wetting in the ion source chamber, including the water and the acidic HCl was seen. By utilizing the hydrogen co-gas, however, this wetting can be mitigated, thereby increasing the safety and longevity of the ion source 108.

The inventors have discovered that the introduction of hydrogen indicated a clear sign of reaction, including a formation of a powder associated with sides of interior housing surfaces of the ion source 108, as well as a reduced Cl+(amu −35 and 37) beam intensity, which is a sign of a chemical reaction taking place. AlCl₃ neutrals and AlClₓ, for example, will deposit on the cooler ion source vacuum chamber walls, and being hygroscopic, such deposits will readily absorb water when the ion source chamber is vented to atmosphere. If the deposits do absorb water, the following reaction can occur:

Al(H₂O)6Cl₃→Al(OH)₃+3 HCl+3 H₂O (3).

The present disclosure appreciates that the formation of HCl can be a safety issue, whereby a negative pressure exhaust can be utilized for the chamber until the deposits or coatings are fully reacted. The water (H₂O) in equation (3) may be present on surfaces (e.g., source chamber walls or other interior surfaces) of the ion source 108 from previous exposure to atmosphere, whereby the water may evolve from such surfaces when subjected to heat from the ion source. Accordingly, the volatile material may be further pumped away utilizing one or more vacuum pumps 128 (e.g., a high vacuum pump) associated with the process chamber 122 in equation (3).

It is noted that the present disclosure further contemplates the hydrogen co-gas source 145 providing other hydrogen-containing co-gases, such as phosphine (PH₃) or hydrogen gas (H₂). The hydrogen co-gas source 145 thus provides for the in-situ introduction of a hydrogen co-gas to the system 100 of FIG. 1. Using phosphine as a co-gas, for example, may be preferable over the use of hydrogen has (H₂), as high-pressure (e.g., bottled) hydrogen gas is highly volatile and often not permitted in fabrication facilities due to its hazardous and explosive nature.

The present disclosure further appreciates that a similar performance and chemistry with hydrogen co-gas can also apply to other chlorine-based ion source materials, such as germanium (iv) chloride, indium (i) chloride, indium (iii) chloride, gallium (ii) chloride, and gallium (iii) chloride, among other chlorides. As such, the inventors contemplate any chlorine-based dopant material to fall within the scope of the present disclosure.

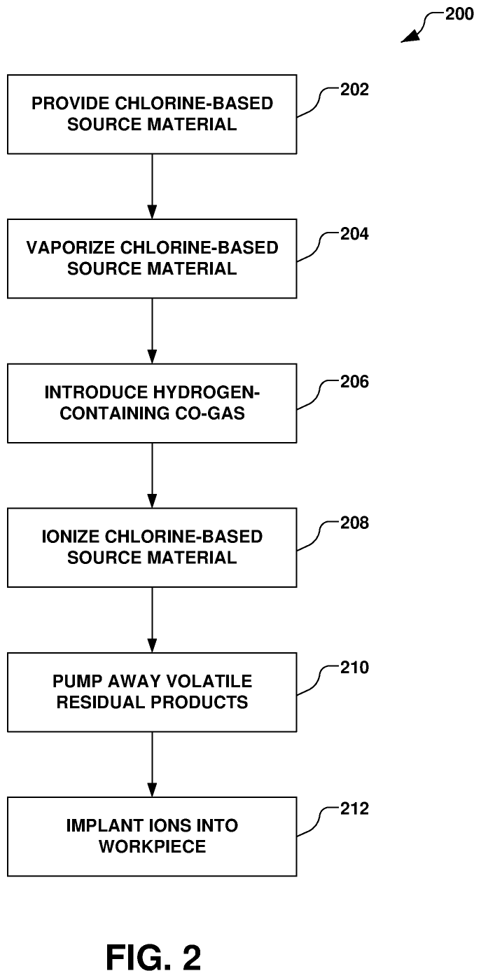

FIG. 2 illustrates an exemplary method 200 for implanting ions into a workpiece. While it is to be understood that the method 200 can comprise an implantation of aluminum ions through the use of aluminum trichloride, it shall be appreciated that the method may be similarly practiced with any chlorine-based source material. It should be further noted that while exemplary methods are illustrated and described herein as a series of acts or events, it will be appreciated that the present invention is not limited by the illustrated ordering of such acts or events, as some steps may occur in different orders and/or concurrently with other steps apart from that shown and described herein, in accordance with the invention. In addition, not all illustrated steps may be required to implement a methodology in accordance with the present invention. Moreover, it will be appreciated that the methods may be implemented in association with the systems illustrated and described herein as well as in association with other systems not illustrated.

In accordance with one exemplary aspect, in act 202 of FIG. 2, aluminum trichloride source material is provided. The aluminum trichloride source material, for example, may be in a solid-form or powder-form. In act 204, for example, the aluminum trichloride (AlCl₃) source material is vaporized and provided to an ion source. In act 206, a hydrogen co-gas is provided or otherwise introduced to the ion source. The hydrogen co-gas, for example, comprises one or more of hydrogen gas and phosphine gas. In act 208, the aluminum trichloride source material is ionized in the ion source, wherein the hydrogen co-gas reacts with the vaporized aluminum trichloride within the ion source to produce volatile hydrogen chloride (HCl) gas. In act 210, the volatile hydrogen chloride gas is pumped away or otherwise removed via a vacuum system. Further, in act 212, aluminum ions from the ionized aluminum chloride source material are implanted into a workpiece.

Although the invention has been shown and described with respect to a certain embodiment or embodiments, it should be noted that the above-described embodiments serve only as examples for implementations of some embodiments of the present invention, and the application of the present invention is not restricted to these embodiments. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application. Accordingly, the present invention is not to be limited to the above-described embodiments, but is intended to be limited only by the appended claims and equivalents thereof.

1. An ion implantation system, comprising:
an aluminum trichloride source material;
an ion source configured to ionize the aluminum trichloride source material and form an ion beam therefrom, and whereby the ionization of the aluminum trichloride source material further forms a by-product comprising a non-conducting material containing chlorine;
a hydrogen introduction apparatus configured to introduce a reducing agent comprising hydrogen to the ion source, wherein the reducing agent is configured to alter a chemistry of the non-conducting material to produce a volatile gas by-product;
a beamline assembly configured to selectively transport the ion beam; and
an end station configured to accept the ion beam for implantation of ions into a workpiece.

2. The ion implantation system of claim 1, wherein the hydrogen introduction apparatus comprises a hydrogen co-gas source, wherein the hydrogen from the reducing agent alters the chemistry of the non-conducting material to produce hydrogen chloride.

3. The ion implantation system of claim 1, wherein the hydrogen introduction apparatus comprises a pressurized gas source.

4. The ion implantation system of claim 3, wherein the pressurized gas source comprises one or more of hydrogen gas and phosphine.

5. The ion implantation system of claim 1, wherein the non-conducting material containing chlorine comprises a molecule in the form of AlClₓ, where x is a positive integer.

6. The ion implantation system of claim 1, further comprising a vacuum system configured to substantially evacuate one or more enclosed portions of the ion implantation system.

7. The ion implantation system of claim 6, wherein the one or more enclosed portions of the ion implantation system comprise the ion source.

8. The ion implantation system of claim 1, wherein the aluminum trichloride source material is in one of a solid form or a powder form.

9. The ion implantation system of claim 8, further comprising a source material vaporizer operably coupled to the ion source, wherein the source material vaporizer is configured to vaporize the aluminum trichloride source material.

10. An ion implantation system, comprising:
a chlorine-based source material;
an ion source configured to ionize the chlorine-based source material and form an ion beam therefrom, and whereby the ionization of the chlorine-based source material further forms a by-product comprising a non-conducting material containing chlorine;
a hydrogen introduction apparatus configured to introduce a reducing agent comprising hydrogen to the ion source, wherein the reducing agent is configured to alter a chemistry of the non-conducting material to produce a volatile gas by-product;
a beamline assembly configured to selectively transport the ion beam; and
an end station configured to accept the ion beam for implantation of ions into a workpiece.

11. The ion implantation system of claim 10, wherein the hydrogen introduction apparatus comprises a hydrogen co-gas source, wherein the hydrogen from the reducing agent alters the chemistry of the non-conducting material to produce hydrogen chloride.

12. The ion implantation system of claim 10, wherein the hydrogen introduction apparatus comprises a pressurized gas source.

13. The ion implantation system of claim 12, wherein the pressurized gas source comprises one or more of hydrogen gas and phosphine.

14. The ion implantation system of claim 10, wherein the non-conducting material containing chlorine comprises a molecule in the form of AlClₓ, where x is a positive integer.

15. The ion implantation system of claim 10, further comprising a vacuum system configured to substantially evacuate one or more enclosed portions of the ion implantation system.

16. The ion implantation system of claim 15, wherein the one or more enclosed portions of the ion implantation system comprise the ion source.

17. The ion implantation system of claim 10, wherein the chlorine-based source material is in one of a solid form or a powder form.

18. The ion implantation system of claim 17, further comprising a source material vaporizer operably coupled to the ion source, wherein the source material vaporizer is configured to vaporize the chlorine-based source material.

19. The ion implantation system of claim 10, wherein the chlorine-based source material comprises one of aluminum trichloride, germanium (iv) chloride, indium (i) chloride, indium (iii) chloride, gallium (ii) chloride, and gallium (iii) chloride.

20. A method for implanting aluminum ions into a workpiece, the method comprising:
vaporizing an aluminum trichloride source material;
providing the vaporized aluminum trichloride source material to an ion source of an ion implantation system;
providing a hydrogen co-gas to the ion source;
ionizing the aluminum trichloride source material in the ion source, wherein the hydrogen co-gas reacts with the vaporized aluminum trichloride source material within the ion source to produce volatile hydrogen chloride gas;
removing the volatile hydrogen chloride gas via a vacuum system; and
implanting aluminum ions from the ionized aluminum trichloride source material into a workpiece.

21. The method of claim 20, wherein the aluminum trichloride source material is initially in one of a solid form or a powder form.

22. The method of claim 20, wherein providing the hydrogen co-gas to the ion source comprises providing one or more of hydrogen gas and phosphine to the ion source.

23. A method for implanting ions into a workpiece, the method comprising:
vaporizing a chlorine-based source material;
providing the vaporized chlorine-based source material to an ion source of an ion implantation system;
providing a hydrogen co-gas to the ion source;
ionizing the chlorine-based source material in the ion source, wherein the hydrogen co-gas reacts with the vaporized chlorine-based source material within the ion source to produce volatile hydrogen chloride gas;
removing the volatile hydrogen chloride gas via a vacuum system; and
implanting ions from the chlorine-based source material into a workpiece.

24. The method of claim 23, wherein the chlorine-based source material is initially in one of a solid or a powder form.

25. The method of claim 23, wherein the chlorine-based source material comprises one of aluminum trichloride, germanium (iv) chloride, indium (i) chloride, indium (iii) chloride, gallium (ii) chloride, and gallium (iii) chloride.

26. The method of claim 23, wherein providing the hydrogen co-gas to the ion source comprises providing one or more of hydrogen gas and phosphine to the ion source.
